(19) United States
(12) Patent Application Publication
(10) Pub. No.: US 2014/0069334 A1
(43) Pub. Date: Mar. 13, 2014

(54) TEMPERATURE CONTROL OF SEMICONDUCTOR PROCESSING CHAMBERS BY MODULATING PLASMA GENERATION ENERGY

(71) Applicants: Kyle Petersen, San Jose, CA (US); Jae Yeol Park, San Ramon, CA (US); Michael Nam, San Jose, CA (US); David Gunther, Oakland, CA (US)

(72) Inventors: Kyle Petersen, San Jose, CA (US); Jae Yeol Park, San Ramon, CA (US); Michael Nam, San Jose, CA (US); David Gunther, Oakland, CA (US)

(73) Assignee: Semicat, Inc., Milpitas, CA (US)

(21) Appl. No.: 13/609,182

(22) Filed: Sep. 10, 2012

(51) Int. Cl. H05H 1/46; H01L 21/66

(52) U.S. Cl. 118/696; 315/111.21

(57) ABSTRACT

Embodiments relate generally to semiconductor device fabrication and processes, and more particularly, to an apparatus and a system that regulates the amount of thermal energy in a semiconductor processing chamber during semiconductor device fabrication and processes. In one embodiment, an apparatus includes a cavity environment controller and a pedestal temperature controller coupled to a semiconductor processing chamber. The pedestal temperature controller is configured to regulate the temperature of the semiconductor processing chamber through a pedestal disposed at the bottom of the semiconductor processing chamber.

### CROSS REFERENCE TO RELATED APPLICATIONS

This application is related to U.S. Nonprovisional application Ser. No. 13/______, filed concurrently and having Attorney Docket No. SEM-006, which is hereby incorporated by reference for all purposes.

### BRIEF DESCRIPTION OF THE INVENTION

Embodiments relate generally to semiconductor device fabrication and processes, and more particularly, to an apparatus and a system that regulates the amount of thermal energy in a semiconductor processing chamber during semiconductor device fabrication and processes.

### BACKGROUND OF THE INVENTION

Traditional techniques for fabricating semiconductors include well-established deposition methods, such as physical vapor deposition (“PVD”), which are carried out in semiconductor processing chambers to deposit thin films on to semiconductor substrates to form electronic devices. During traditional fabrication processes, conventional semiconductor processing chambers can withstand the heat generated by the plasma and provide an adequate processing environment for depositing thin films upon semiconductor substrates. However, as the desired thickness of the deposited thin films increases, higher deposition power and longer processing times are typically required, leading to more severe thermal conditions inside the semiconductor deposition chamber. The amount of heat generated by the plasma in the semiconductor process chamber can cause significant defects on the wafer, such as whiskers and extrusions, which can negatively impact the performance of the electronic devices. Whiskers are small metal hairs that can cause short circuits on the electronic device. The relatively large amount of heat generated by the plasma can also cause the target to melt and to drip on to the wafer.

One traditional approach to reduce heat-related defects is to use a lower power during deposition, but at significantly increased deposition times. Another traditional approach is to operate at normal power, but implement significant idle time to break up the deposition steps so the wafer does not get too hot during deposition. At least one of the drawbacks of these traditional approaches is that they significantly increase fabrication time and significantly decrease yield and process efficiency.

In view of the foregoing, it is desirable to provide an apparatus and a system for overcoming the drawbacks of the conventional semiconductor processing chamber to decrease fabrication time and to increase yield with reduced types or numbers of defects.

### BRIEF DESCRIPTION OF THE FIGURES

The invention is more fully appreciated in connection with the following detailed description taken in conjunction with the accompanying drawings, in which:

FIG. 1 depicts an example of a system for controlling the amount of thermal energy, or heat, in a semiconductor processing chamber, according to various embodiments.

FIG. 2 depicts an example of a system configured to regulate thermal energy during semiconductor processing, according to various embodiments.

FIG. 3 depicts an example of a system configured to regulate thermal energy during semiconductor processing, according to various embodiments.

FIG. 4 depicts an example of a flow to regulate thermal energy in the source cavity in a semiconductor process chamber temperature control system during a semiconductor fabrication process, according to various embodiments.

FIG. 5 depicts a plot illustrating the temperature of the source cavity versus time during a semiconductor fabrication process, according to various embodiments.

FIG. 6 depicts an example of a system configured to regulate thermal energy in a semiconductor processing chamber during semiconductor processing, according to various embodiments.

FIG. 7 depicts an example of a system configured to regulate thermal energy in a semiconductor processing chamber during semiconductor processing, according to various embodiments.

FIG. 8 depicts an example of a flow to control the amount of thermal energy in a pedestal disposed in the semiconductor processing chamber in a semiconductor process chamber temperature control system during a semiconductor fabrication process, according to various embodiments.

FIG. 9 depicts a plot illustrating the linear percentage relationship between the plasma power set point and the pedestal power set point, according to various embodiments.

FIG. 10 depicts an example of the semiconductor processing chamber temperature control system as part of a semiconductor processing system, according to various embodiments.

### DETAILED DESCRIPTION

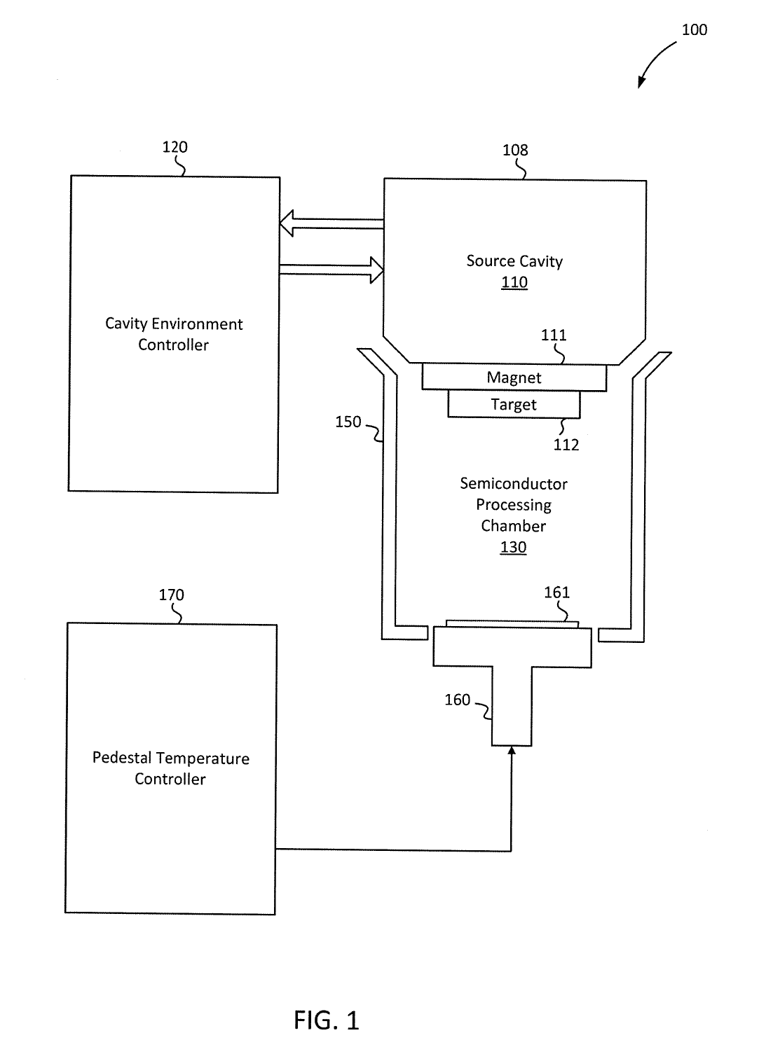

FIG. 1 depicts an example of a system for controlling the amount of thermal energy, or heat, in a semiconductor processing chamber 130 in accordance with at least one embodiment. Diagram 100 depicts a semiconductor processing chamber temperature control system. As shown in diagram 100, the semiconductor processing chamber temperature control system can include a source cavity 110, a cavity environment controller 120, a semiconductor processing chamber 130, a pedestal 160, and a pedestal temperature controller 170. In some embodiments, the source cavity includes a magnet 111 and a target 112. In the example shown, the source cavity 110 is a housing 108 comprising a cavity configured to include a fluid, such as a gas or liquid. In some embodiments, the housing of source cavity 110 may also have a surface disposed adjacent to target 112, or magnet 111, or both. Target 112, or magnet 111, or both can be arranged at the top of semiconductor processing chamber 130. As an example, during semiconductor processing, target 112 can be made of aluminum and used to create an aluminum-based plasma, and magnet 112 is used to control how the aluminum particles in the plasma are deposited onto a wafer 161, such as a semiconductor substrate or a silicon wafer. Target 112 is not limited to aluminum and can be composed of any known element. In some embodiments, a cavity environment controller 120 can be coupled to source cavity 110 to regulate the temperature and/or thermal energy, of the fluid in source cavity 110. In this example, the fluid in source cavity 110 is transferred to cavity environment controller 120 where the temperature and/or thermal energy in the fluid is reduced or increased as needed to bring the temperature and/or thermal energy of the fluid to a target temperature. The fluid is then returned to source cavity 110 to establish the target temperature in source cavity 110. As used herein, the term “target temperature” can refer to the desired temperature to be established in source cavity 110 at any given time (e.g., during a semiconductor process or when system is idle).

According to various embodiments, the semiconductor processing chamber temperature control system of diagram 100 includes a pedestal 160 disposed in the enclosed semiconductor processing chamber 130. In the example shown, pedestal 160 can be formed from a conducting material (e.g., heat and/or electrically conductive), such as steel, and disposed at the bottom of semiconductor processing chamber 130. In some embodiments, pedestal 160 is used to hold or support wafer 161, allowing wafer 161 to be exposed to the plasma in semiconductor processing chamber 130 during a semiconductor fabrication process. In at least one embodiment, pedestal 160 allows wafer 161 to be positioned so that a layer of material (e.g., aluminum) may be deposited onto wafer 161 from an aluminum-based plasma in semiconductor processing chamber 130. In addition to deposition, the semiconductor processing chamber temperature control system can also control the temperature in semiconductor processing chamber 130 while performing other processing operations, such as etching. In some embodiments, a pedestal temperature controller 170 can be coupled to pedestal 160 to regulate the amount of thermal energy in pedestal 160 by controlling the amount of energy provided to pedestal 160. In some implementations, the amount of energy provided to pedestal 160 can be used to control the amount of thermal energy in semiconductor processing chamber 130. As an example, if the energy provided to pedestal 160 causes the thermal energy in pedestal 160 to be less than the thermal energy of semiconductor processing chamber 130, then pedestal 160 can operate as a heat sink to absorb or withdraw thermal energy from semiconductor processing chamber 130, thus lowering the amount of thermal energy in semiconductor processing chamber 130. Note that in other embodiments, pedestal 160 can operate as a heater to increase the amount of thermal energy in semiconductor processing chamber 130. Thermal energy includes heat and energy that results in system temperature.

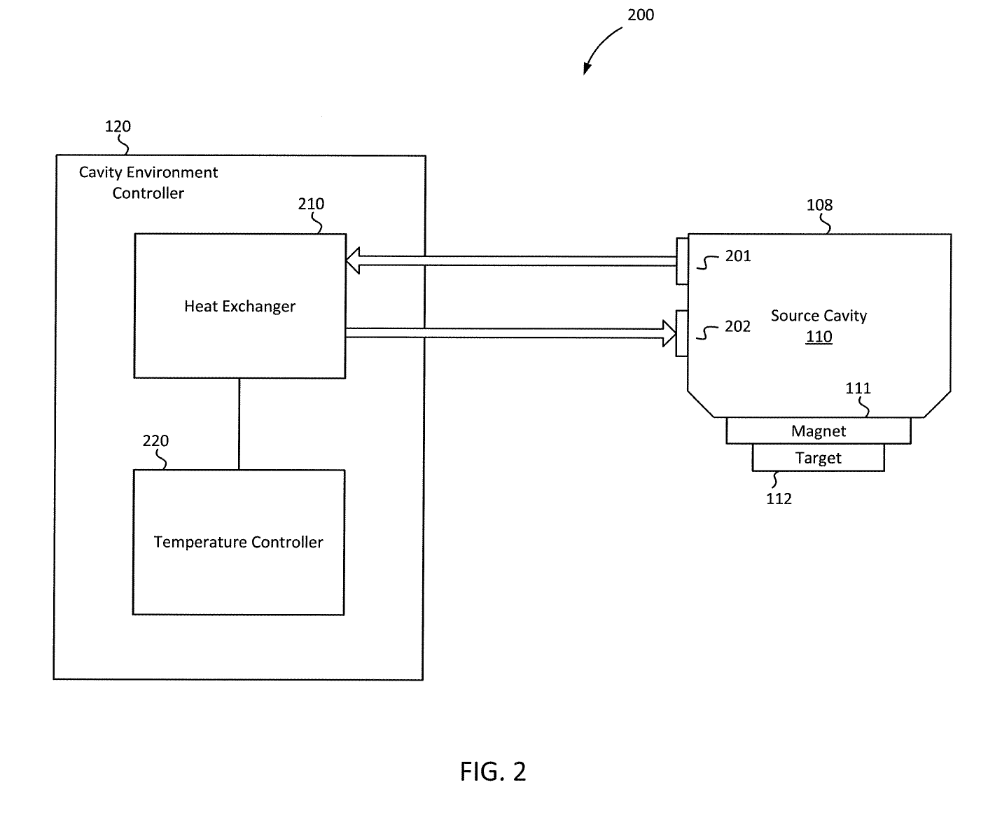

FIG. 2 depicts an example of a system configured to regulate thermal energy during semiconductor processing in accordance with at least one embodiment. Diagram 200 depicts a cavity environment controller 120 coupled to a source cavity 110. In some examples, elements in FIG. 2 can have structures and/or functions equivalent to elements in FIG. 1 that are named and/or numbered similarly. In the example shown, cavity environmental controller 120 can include a heat exchanger 210 and a temperature controller 220. The example further shows source cavity 110 coupled to heat exchanger 120 in cavity environment controller 120 through an input port 202 and an output port 201 on source cavity 110. During semiconductor processing, the plasma in the semiconductor processing chamber generates a significant amount of thermal energy in the chamber. In some embodiments, some of the thermal energy generated by the plasma is absorbed by target 112, thereby heating it up. Some of the thermal energy is then transferred from target 112 and magnet 111 and absorbed into the fluid in source cavity 110. This thermal energy transfer can cause the fluid in source cavity 110 to heat up, and in some embodiments, may require removal of the thermal energy from the fluid in source cavity 110 to establish a target temperature in source cavity 110. By regulating the target temperature in source cavity 110, cavity environment controller 120 is also regulating the temperature of magnet 111, or target 112, or both, and in turn controls the amount of thermal energy removed from the semiconductor processing chamber 130 to prevent semiconductor processing chamber 130 from over-heating since thermal energy from semiconductor processing chamber 130 can be absorbed through the target and into the fluid in source cavity 110 and then removed from the fluid. During semiconductor processing, an amount of thermal energy is required in semiconductor processing chamber 130 to create the plasma. In some embodiments, the amount of thermal energy in semiconductor processing chamber 130 can be regulated to insure that the amount of thermal energy in semiconductor processing chamber 130 is high enough to create the plasma, but not so high that the amount of thermal energy in semiconductor processing chamber 130 becomes excessive and causes heat-related defects during the semiconductor fabrication process.

In the example shown in FIG. 2, the thermal energy in the fluid is removed by heat exchanger 210, which in some embodiments, can be separate from or integrated into the cavity environment controller. As used herein, a heat exchanger is a device that can transfer thermal energy from one medium (e.g., a fluid and/or substance) to another. Some examples of heat exchangers are, but not limited to, chillers, air conditioners, and heat sinks. As shown in the example, the fluid in source cavity 110 is transferred to heat exchanger 210 through output port 201. Once the fluid arrives in heat exchanger 210, heat exchanger 210 will then operate to remove a desired amount of thermal energy from the fluid before returning the fluid back to source cavity 110 through input port 202 of source cavity 110.

Other embodiments can have a temperature controller 220 coupled to heat exchanger 210. Temperature controller 220 can be configured to monitor and regulate the temperature in source cavity 110 at a temperature set point by comparing data representing the temperature of the fluid to data representing the temperature set point, and then communicating to heat exchanger 210 an amount of thermal energy to remove from the fluid to modify the temperature of the fluid to match the temperature set point. The temperature modified fluid is then returned to source cavity 110 to establish a target temperature in source cavity 110. As used herein, the term “temperature set point” can refer to a desired temperature to be established in the heat exchanger 210 before the fluid is returned to the source cavity 110 to establish a target temperature in the source cavity 110. In some embodiments, the target temperature in source cavity 110 can be equal to the temperature set point since no thermal energy is lost or gained in the fluid during the transfer from heat exchanger 210 back to source cavity 110. In some embodiments, the target temperature in the source cavity can be different from the temperature set point because thermal energy can be lost or gained during the transfer from heat exchanger 210 back to source cavity 110 (e.g., the fluid has to travel a longer distance between heat exchanger 210 and source cavity 110). As shown in the example, temperature controller 220 is integrated into cavity environment controller 120 along with heat exchanger 210, but is not so limited.

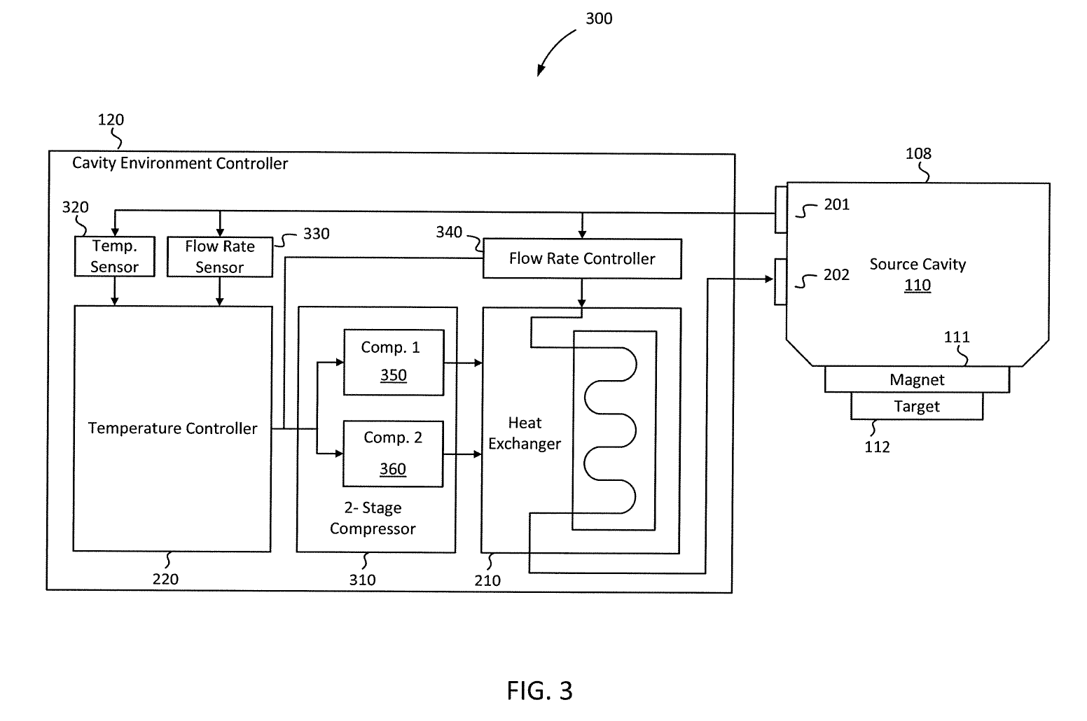

FIG. 3 depicts another example of an embodiment configured to regulate thermal energy during semiconductor processing in accordance with at least one embodiment. Diagram 300 depicts cavity environmental controller 120 coupled to source cavity 110. In some examples, elements in FIG. 3 can have structures and/or functions equivalent to elements in FIG. 1 and FIG. 2 that are named and/or numbered similarly. In the example shown, cavity environment controller 120 can include temperature controller 220, heat exchanger 210, a compressor 310, a temperature sensor 320, a flow rate sensor 330, and a flow rate controller 340 coupled to source cavity 110 through input port 202 and output port 201 on source cavity 110. During semiconductor processing, the plasma in the semiconductor processing chamber generates an amount of thermal energy in the chamber. In some embodiments, some of the thermal energy generated by the plasma is absorbed by target 112, thereby heating it up. Some of the thermal energy is then transferred from target 112 and magnet 111 and absorbed into the fluid in source cavity 110. This thermal energy transfer can cause the fluid in source cavity 110 to heat up, and in some embodiments, may require removal of the thermal energy from the fluid in source cavity 110 to establish a target temperature in source cavity 110. By regulating the target temperature in source cavity 110, cavity environment controller 120 is also regulating the temperature of magnet 111, or target 112, or both, and in turn controls the amount of thermal energy removed from the semiconductor processing chamber 130 to prevent semiconductor processing chamber 130 from over-heating since thermal energy from semiconductor processing chamber 130 can be absorbed through the target and into the fluid in source cavity 110 and then removed from the fluid.

In the example shown in FIG. 3, the thermal energy of the fluid is regulated and controlled by temperature controller 220. As shown, temperature controller 220 can receive an input from temperature sensor 320, which can detect the temperature or amount of thermal energy in the fluid, and flow rate sensor 330, which can detect the flow rate of the fluid transfer between source cavity 110 and heat exchanger 210, and temperature controller 220 can use this data to regulate the thermal energy in the fluid to match a temperature set point to establish a target temperature in source cavity 110. In some embodiments, the thermal energy in the fluid can be regulated by changing the flow rate of the fluid through the heat exchanger by using a flow rate controller 340, wherein the flow rate of the fluid determines how much thermal energy is exchanged with the fluid in heat exchanger 210. For example, if the flow rate of the fluid going into the heat exchanger 210 is decreased, the fluid passes more slowly through heat exchanger 210, exposing the fluid to heat exchanger 210 for a longer period of time, and therefore, adding or removing a higher quantity of thermal energy from the fluid. Likewise in another example, if the flow rate of the fluid going into the heat exchanger 210 is increased, the fluid passes more quickly through heat exchanger 210, exposing the fluid to the heat exchanger for a shorter period of time, thereby adding or removing a lower quantity of thermal energy from the fluid.

In some embodiments, the thermal energy in the fluid can be regulated by increasing the amount of coolant in the heat exchanger to lower the thermal energy in heat exchanger 210, and therefore lowering the thermal energy of the fluid passing through heat exchanger 210. In the example shown in FIG. 3, a two-stage compressor 310 can include a first compressor 350 and a second compressor 360 and can be coupled to heat exchanger 210 to increase the thermal exchanging capacity of heat exchanger 210. In some embodiments, temperature controller 220 can be coupled to two-stage compressor 310 to determine how much coolant to add to heat exchanger 210 to regulate the fluid at the temperature set point and the target temperature in source cavity 110. As shown in FIG. 3, when temperature controller 220 determines that thermal energy in the fluid needs to be reduced, temperature controller 220 can send a signal to first compressor 350 of two-stage compressor 310 to add coolant to heat exchanger 210 to increase the thermal exchanging capacity of heat exchanger 210 to lower the temperature in the fluid. Furthermore, if temperature controller 220 determines that thermal energy in the fluid needs to be further reduced beyond the thermal exchanging capacity of heat exchanger 210 provided by first compressor 350, temperature controller 220 can send a signal to second compressor 360 to add more coolant to heat exchanger 210 to increase the thermal exchanging capacity of heat exchanger 210 even more. Note that in some embodiments, one compressor can be used for the entire range of temperature set points, while in other embodiments, more than two compressors can be used.

In some embodiments, the thermal energy of the fluid can be regulated by using a combination of changing the flow rate of the fluid through heat exchanger 210 and increasing the amount of coolant in heat exchanger 210. As an example, temperature controller 220 can be configured to receive data representing the temperature of the fluid from temperature sensor 320 and to detect the flow rate of the fluid from flow rate sensor 330, and determine a combination of how much coolant to add from two-stage compressor 310 to heat exchanger 210 and how much to modify the flow rate of the fluid into heat exchanger 210 to regulate the fluid at the desired temperature set point to establish a target temperature in source cavity 110.

In view of the foregoing, a semiconductor processing chamber temperature controls system of various embodiments, as well as the processes of using the same, can provide the structures and/or functionalities for regulating the amount of thermal energy in a semiconductor processing chamber. In some embodiments, a cavity environment controller can be used to control the amount of thermal energy removed from a semiconductor processing chamber to prevent the semiconductor processing chamber from over-heating since thermal energy from the semiconductor processing chamber can be absorbed through the target and into the fluid in the source cavity and then removed from the fluid. In some embodiments, a heat exchanger can be used to remove a desired amount of thermal energy from the fluid in the source cavity, the desired amount of thermal energy being an amount of thermal energy that is removed to match the temperature of the fluid to the temperature set point before the fluid is returned to the source cavity to establish a target temperature in the source cavity. In some embodiments, the thermal energy in the fluid can be regulated by changing the flow rate of the fluid through the heat exchanger, wherein the flow rate of the fluid determines how much thermal energy is exchanged with the fluid in the heat exchanger.

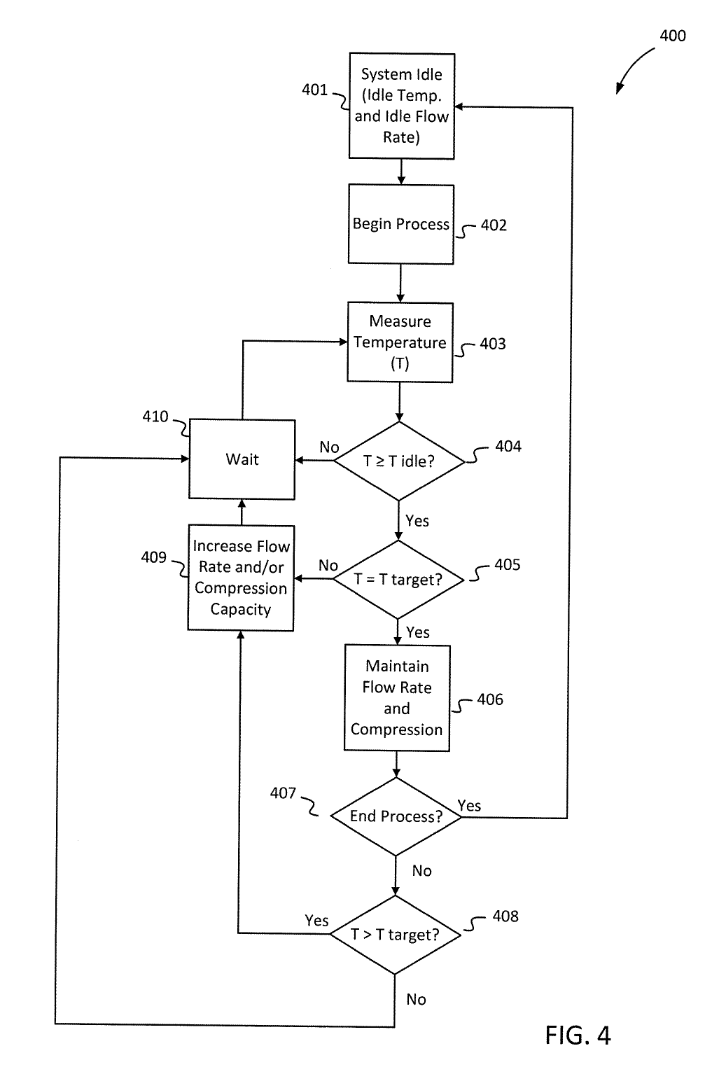

FIG. 4 is a diagram depicting an example of a flow to regulate thermal energy in the source cavity in a semiconductor process chamber temperature control system during a semiconductor fabrication process, according to a specific embodiment. Flow 400 starts at 401. At 401, the semiconductor fabrication process has not yet begun, and the semiconductor processing chamber temperature control system is an idle state. As used herein, the term “idle state” can refer to, at least in some embodiments, when the system is in a standby mode, or when the system is not performing a semiconductor fabrication process, or is waiting for a semiconductor fabrication process to begin. In some embodiments, the idle state can have an idle temperature and an idle flow rate associated with the idle state. As an example, an idle state of an embodiment may be maintained at a target temperature of approximately 12 degrees Celsius in the source cavity while the system is not performing a semiconductor fabrication process and/or is waiting for a semiconductor fabrication process to begin. At 402, the semiconductor fabrication process begins and the system exits the idle state. At 403, when the system has exited the idle state and the semiconductor fabrication process begins, the system will begin measuring the temperature of the system. In some embodiments, this temperature is measured by configuring a temperature controller to measure the thermal energy of the fluid in the source cavity as shown in FIG. 3. A determination is made at 404 as to whether the measured temperature is greater than the idle temperature. If not, flow passes to 410, but if so, flow passes to 405. At 410, the system waits a period of time before measuring the temperature of the source cavity again. In various embodiments, the period of time to wait before measuring the temperature again can vary, keeping in mind that the more frequently the temperature is measured (i.e., shorter wait period), the more quickly the system can respond to temperature changes. At 405, a determination is made as to whether the temperature of the source cavity has reached a target temperature. If not, flow passes to 409, but if so, flow passes to 406. At 409, the flow rate of the fluid through the heat exchanger can be increased and/or coolant can be added by a compressor to the heat exchanger to modify the amount of thermal energy in the fluid, according to various embodiments. Flow 409 then moves to 410 to wait a period of time and then to 403 to repeat the measure of the temperature of the source cavity. At 406, the system maintains the flow rate and/or compression to maintain the temperature in the source cavity at the target temperature. At 407, a determination is made as to whether the semiconductor fabrication process has ended. If so, flow passes to 401, but if not, flow passes to 408. At 401, the system returns to the idle state after the semiconductor fabrication process has ended. At 408, a determination is made as to whether the temperature of the system exceeds the target temperature of the system. If so, flow continues back to 409, and if not, flow continues back to 410. In various embodiments, more or fewer operations or steps can be implemented than is described in FIG. 4.

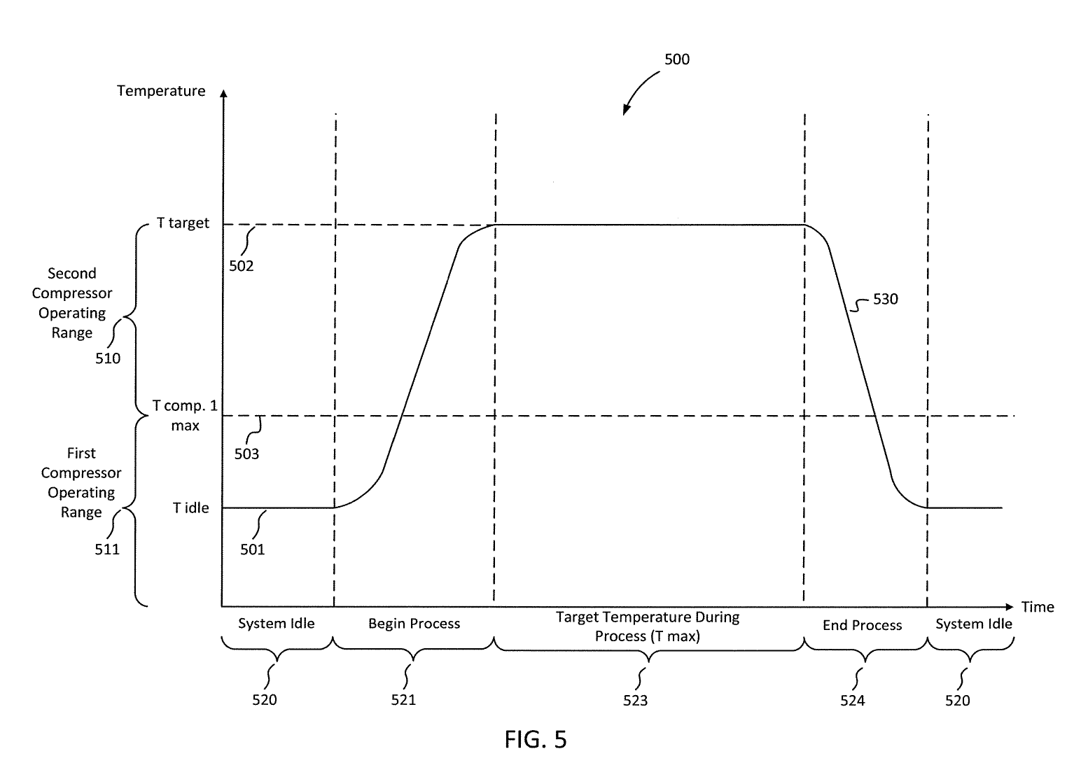

FIG. 5 depicts a plot illustrating the temperature of the source cavity versus time during a semiconductor fabrication process. Plot 500 illustrates the temperature changes during an entire semiconductor fabrication process cycle from beginning to end, according to various embodiments. According to some embodiments, the semiconductor fabrication process begins with the semiconductor fabrication process temperature control system at a system idle state 520, and the temperature of the system is regulated at an idle temperature 501. An example of idle temperature 501 is the target temperature in the source cavity when the system is in an idle state. In a specific embodiment, idle temperature 501 is 12 degrees Celsius. In some embodiments, when the semiconductor fabrication process begins as indicated at section 521, the introduction of plasma into the semiconductor processing chamber causes the temperature of the system to rise. In some embodiments, the temperature controller begins to regulate the temperature as soon as the process begins, and can control how quickly or slowly the temperature rises to a target temperature 502 in the source cavity. Once target temperature 502 is reached in the source cavity, section 523 is entered. Section 523 then shows that the temperature in the source cavity is maintained at target temperature 502 during the semiconductor fabrication process. An example of an embodiment is the temperature controller regulating the thermal energy of the fluid in the source cavity by removing or adding thermal energy to the fluid using a heat exchanger to maintain target temperature 502 in the source cavity. In some embodiments, when the semiconductor fabrication process ends, as indicated by section 524, the system begins to return the temperature of the source cavity back to idle temperature 501, and the time required to return the temperature of the source cavity back to idle temperature 501 can depend on the flow rate and the amount of coolant in the heat exchanger, controlled by a temperature controller. When the temperature of the source cavity is returned to the idle temperature 501, the system goes back to the system idle state indicated by section 520, and stays in the system idle state until the next semiconductor fabrication process begins.

FIG. 5 also depicts a compressor one operating range 511 and a compressor two operating range 510, according to some embodiments. Compressor one operating range 511, in this embodiment, shows the lower range of the cooling capacity of the heat exchanger from the first compressor in a two-stage compressor. An example of the range of temperatures that can be regulated in the compressor one operating range 511 is from idle temperature 501 to compression one maximum temperature 503. Compressor two operating range 510, in this embodiment, shows the extended range of the cooling capacity of the heat exchanger from the second compressor in a two-stage compressor. An example of the range of temperatures that can be regulated in the compressor two operating range 501 is from compression one maximum temperature 503 to target temperature 502. Note that in some embodiments, one compressor and corresponding compressor operating range can be used for the entire range of temperature set points, while in other embodiments, more than two compressors and their corresponding compressor operating ranges can be used.

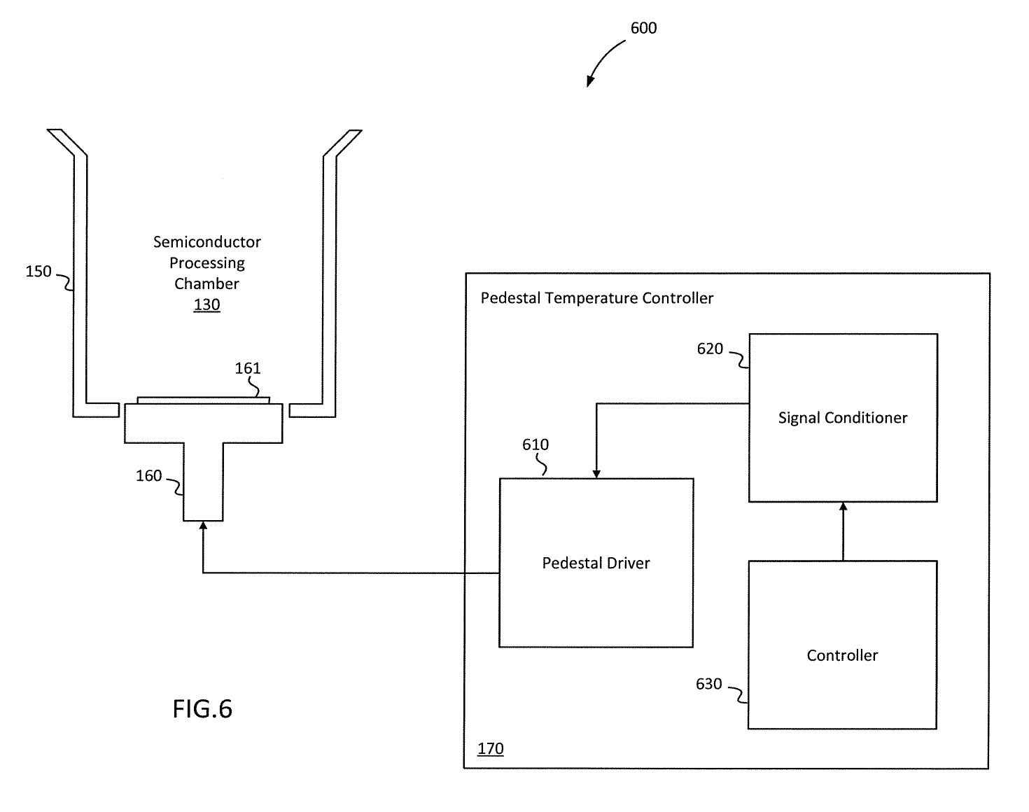

FIG. 6 depicts an example of a system configured to regulate thermal energy during semiconductor processing in accordance with at least one embodiment. Diagram 600 depicts pedestal 160 disposed at the bottom of semiconductor processing chamber 130 coupled to pedestal temperature controller 170. In some embodiments, elements in FIG. 6 can have structures and/or functions equivalent to elements in FIG. 1 that are named and/or numbered similarly. In an embodiment shown in diagram 600, pedestal temperature controller 170 can include a pedestal driver 610, a signal conditioner 620, and a controller 630. Diagram 600 further shows pedestal temperature controller 170 coupled to pedestal 160. During semiconductor processing, the plasma in the semiconductor processing chamber generates a significant amount of thermal energy in semiconductor processing chamber 130. In some embodiments, some of the thermal energy generated by the plasma is absorbed by wafer 161, thereby heating it up, and if wafer 161 absorbs too much thermal energy, the excess thermal energy can increase the chances of heat-related defects on wafer 161. In some embodiments, pedestal 160 is disposed at the bottom of semiconductor processing chamber 130 to support wafer 161. Pedestal 160 can also be configured to receive a pedestal power set point. As used herein, the term “pedestal power set point” can refer to a characteristic of a signal (e.g., a magnitude) representing energy provided to pedestal 160 to provide power and/or thermal energy to pedestal 160. In some embodiments, the semiconductor fabrication process will cause an increase of the amount of thermal energy in semiconductor processing chamber 130 and may require removal of the thermal energy from semiconductor processing chamber 130. In some embodiments, pedestal temperature controller 170 can be configured to modify the pedestal power set point so that pedestal 160 receives less power and/or thermal energy, so that the thermal energy of the pedestal is less than the thermal energy in semiconductor process chamber 130, wherein the relative difference in thermal energy allows pedestal 160 to operate as a heat sink. Pedestal 160 will then absorb thermal energy from semiconductor processing chamber 130, thereby removing the amount of thermal energy and decreasing the temperature in semiconductor processing chamber 130. As an example, pedestal driver 610 can be configured to reduce power output corresponding to the plasma power set point and to thereby operate as a heat exchanger to remove thermal energy from the semiconductor processing chamber.

According to various embodiments, pedestal temperature controller 170 can include pedestal driver 610 and signal conditioner 620. Signal conditioner 620 can be configured to receive a pedestal power set point. The pedestal power set point can be a range of values, for example, from 0 Volts (“V”) to 10 V, wherein 0 V can indicate that no energy is provided to pedestal 160 and the thermal energy of pedestal 160 is at a minimum, and 10 V can indicate that maximum energy is provided to the pedestal 160 and the thermal energy of pedestal 160 is at a maximum. In some embodiments, signal conditioner 620 can send data representing the pedestal power set point to pedestal driver 610, wherein pedestal driver 610 is configured to receive the data representing the pedestal power set point and to generate an alternating current (“AC”) power signal corresponding to the pedestal power set point to send to pedestal 160 so that pedestal 160 can operate as a heat exchanger to remover thermal energy from the semiconductor processing chamber. An AC power signal can be an alternating current signal with an amplitude and duty cycle, but is not so limited. In some embodiments, controller 630 can be coupled to signal conditioner 620, and can be configured to determine whether to modify the pedestal power set point to increase or decrease the energy provided to pedestal 160 to increase or decrease the amount of thermal energy in pedestal 160, thereby using pedestal 160 to control the amount of thermal energy in semiconductor processing chamber 130.

In view of the foregoing, a semiconductor processing chamber temperature controls system of various embodiments, as well as the processes of using the same, can provide the structures and/or functionalities for regulating the amount of thermal energy in a semiconductor processing chamber. In some embodiments, if the energy provided to pedestal 160 causes the thermal energy in pedestal 160 to be less than the thermal energy of semiconductor processing chamber 130, then pedestal 160 can operate as a heat sink to absorb or withdraw thermal energy from semiconductor processing chamber 130, thus lowering the amount of thermal energy in semiconductor processing chamber 130. Note that in other embodiments, pedestal 160 can operate as a heater to increase the amount of thermal energy in semiconductor processing chamber 130.

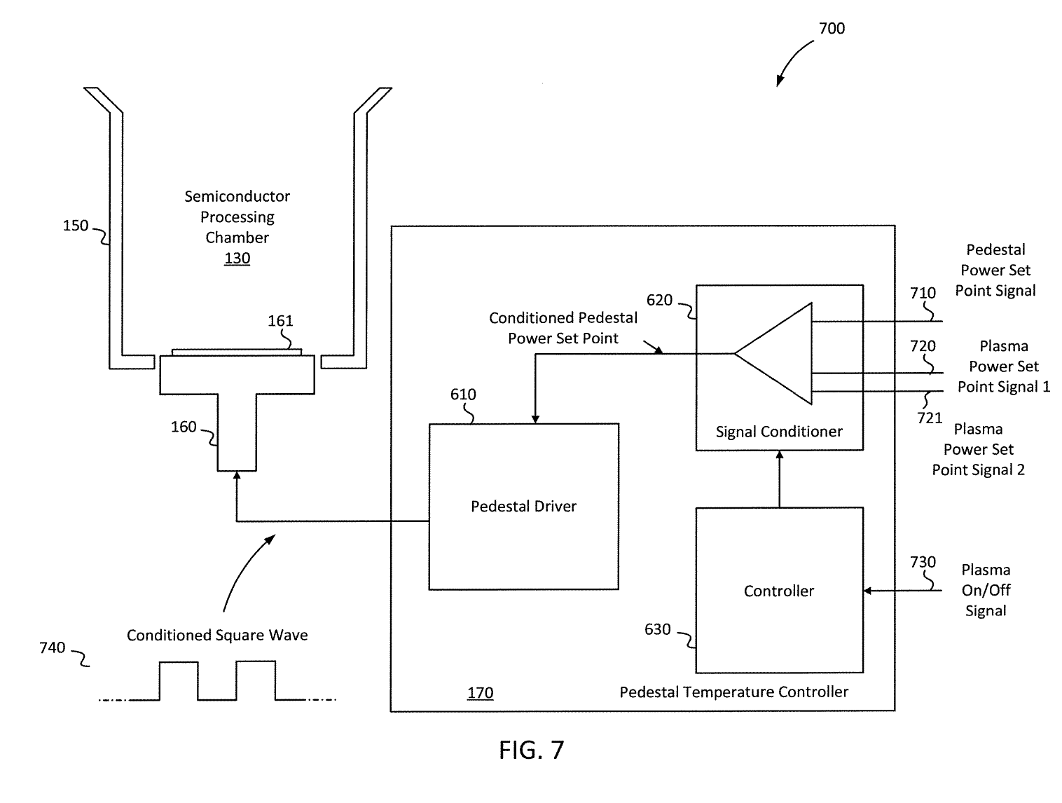

FIG. 7 depicts another example of an embodiment configured to regulate thermal energy during semiconductor processing in accordance with at least one embodiment. Diagram 700 depicts semiconductor processing chamber 130 and pedestal 160 coupled to pedestal temperature controller 170. In some examples, elements in FIG. 7 can have structures and/or functions equivalent to elements in. FIG. 1 and FIG. 6 that are named and/or numbered similarly. In the embodiment shown in FIG. 7, pedestal temperature controller 170 can include pedestal driver 610, signal conditioner 620 configured to receive a pedestal power set point signal 710 and a plasma power set point signal 720, and controller 630 configured to receive a plasma on/off signal 730. As used herein, the term “plasma power set point” can refer, at least in some embodiments, to a signal representing energy provided to semiconductor processing chamber 130 to generate plasma in semiconductor processing chamber 130. The thermal energy generated by the plasma in semiconductor processing chamber 130 can depend on the plasma power set point. In some embodiments, signal conditioner 620 can be configured to include a comparator function (e.g., op amp circuit and/or logic to perform a subtracting function) to compare data representing pedestal power set point signal 710 and data representing plasma power set point signal 720, and controller 630 can deter mine an amount signal conditioner 620 will modify the pedestal power set point to increase or decrease the thermal energy of pedestal 160. The modified pedestal power set point will then become a conditioned pedestal power set point. As used herein, the term “conditioned pedestal power set point” can refer, at least in some embodiments, to a modified pedestal power set point representing a decrease or increase of the energy to pedestal 160 and corresponding decrease or increase in the amount of thermal energy in pedestal 160 to add or remove thermal energy to semiconductor processing chamber 130. In some embodiments, a first plasma power set point signal 720 and a second plasma power set point signal 721 will be first summed, then subtracted from pedestal power set point signal 710, and the maximum sum will still be 10 V, which will result in a conditioned pedestal power set point of 0 V. In some embodiments, pedestal driver 610 receives data representing the conditioned pedestal power set point and to generate an AC power signal corresponding to the conditioned pedestal power set point to send to pedestal 160, thereby modifying the amount of thermal energy in pedestal 160 to correspond to the amount of thermal energy desired in pedestal 160 relative to the amount of thermal energy in semiconductor processing chamber 130. In some embodiments, the AC power signal generated by pedestal driver 170 can be an AC square wave 740 with an amplitude and a duty cycle. For example, if controller 630 determines that the amount of thermal energy in semiconductor processing chamber 130 needs to be reduced, then controller 630 tells signal conditioner to modify the pedestal power set point as a function of an amount the thermal energy in semiconductor processing chamber 130 can be reduced. The conditioned pedestal power set point can then be received by pedestal driver 610 to generate AC square wave 740 based on the conditioned pedestal power set point, and then applied to pedestal 160, wherein the amount of thermal energy in pedestal 160 is decreased. In some embodiments, pedestal driver 160 can generate a range of energy applied to pedestal 160 by modifying a combination of the amplitude and/or duty cycle of the AC power signal. In other embodiments, thermal energy of the pedestal is determined by the amplitude and/or duty cycle of the AC power signal. In some embodiments, the amplitude and/or duty cycle of the AC power signal can be modulated as a function of the conditioned pedestal power set point.

In some embodiments, controller 630 can receive a plasma on/off signal 730 to determine whether plasma is present in semiconductor processing chamber 130, and if plasma on/off signal 730 indicates plasma is present, then controller 630 can begin regulating the amount of thermal energy in semiconductor processing chamber 130 by controlling the amount of thermal energy in pedestal 160.

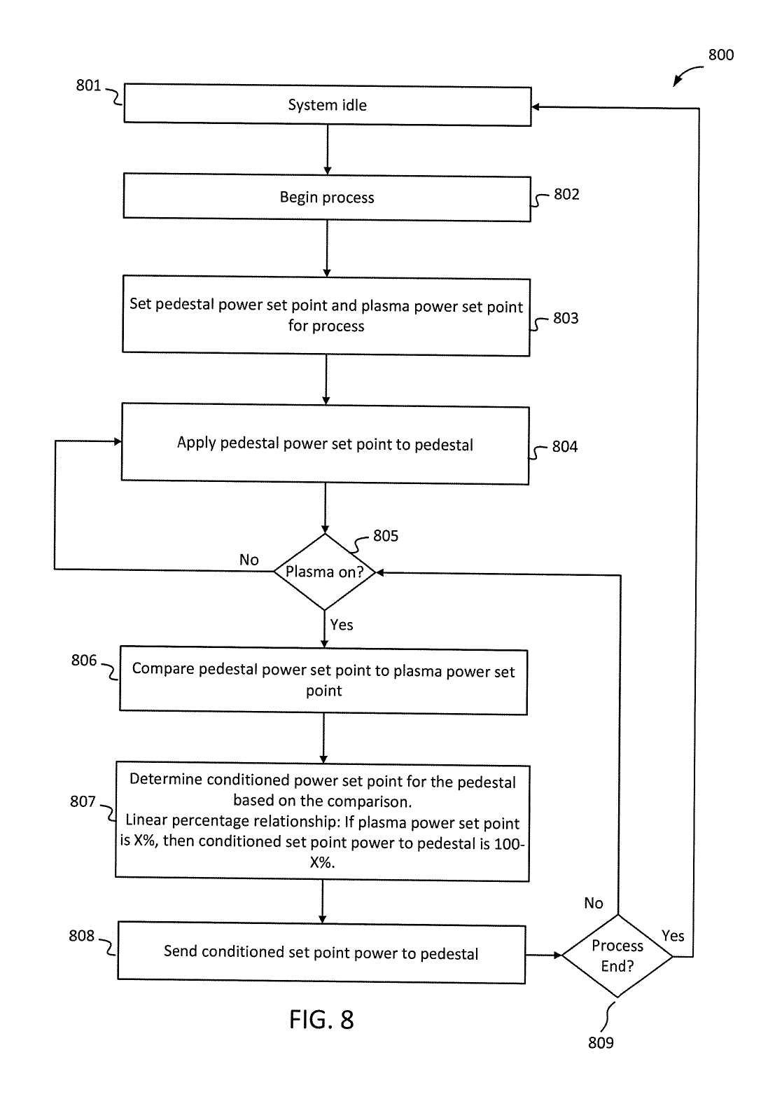

FIG. 8 is a diagram depicting an example of a flow to control the amount of thermal energy in a pedestal disposed in the semiconductor processing chamber in a semiconductor process chamber temperature control system during a semiconductor fabrication process, according to a specific embodiment. Flow 800 starts at 801. At 801, the system is in an idle state. In some embodiments, the pedestal is not receiving power and/or has a minimal amount of thermal energy when the system is in the idle state. When the semiconductor fabrication process begins, flow continues to 802. Flow then continues to 803 where the pedestal power set point and the plasma power set point are set for the semiconductor fabrication process. Flow then continues to 804 where the pedestal power set point is applied to the pedestal to establish an amount of thermal energy in the pedestal. At 805, a determination is made as to whether plasma is present in the semiconductor processing chamber. If not, flow goes back to 804, but if so, flow continues to 806. At 806, the system compares the pedestal power set point to the plasma power set point. At 807, the system determines the conditioned pedestal power set point based on the comparison of the pedestal power set point and the plasma power set point. In some embodiments, the plasma power set point and the conditioned pedestal power set point can have a linear percentage relationship. For example, if the plasma power set point is set to 70% of the maximum plasma power, then the signal conditioner can modify the pedestal power set point to a conditioned pedestal power set point that is 30% of the maximum power that can be applied to the pedestal, or if the plasma power set point is set to X percent of the maximum plasma power, then the conditioned pedestal power set point is set to 100 minus X percent, of the maximum power that can be applied to the pedestal.

At 808, the pedestal receives an AC power signal representing the conditioned pedestal power set point to establish the power and/or the amount of thermal energy in the pedestal. At 809, a determination is made as to whether the semiconductor fabrication process has ended. If not, flow goes back to 805, but if so, flow goes back 801 and the system returns to the idle state.

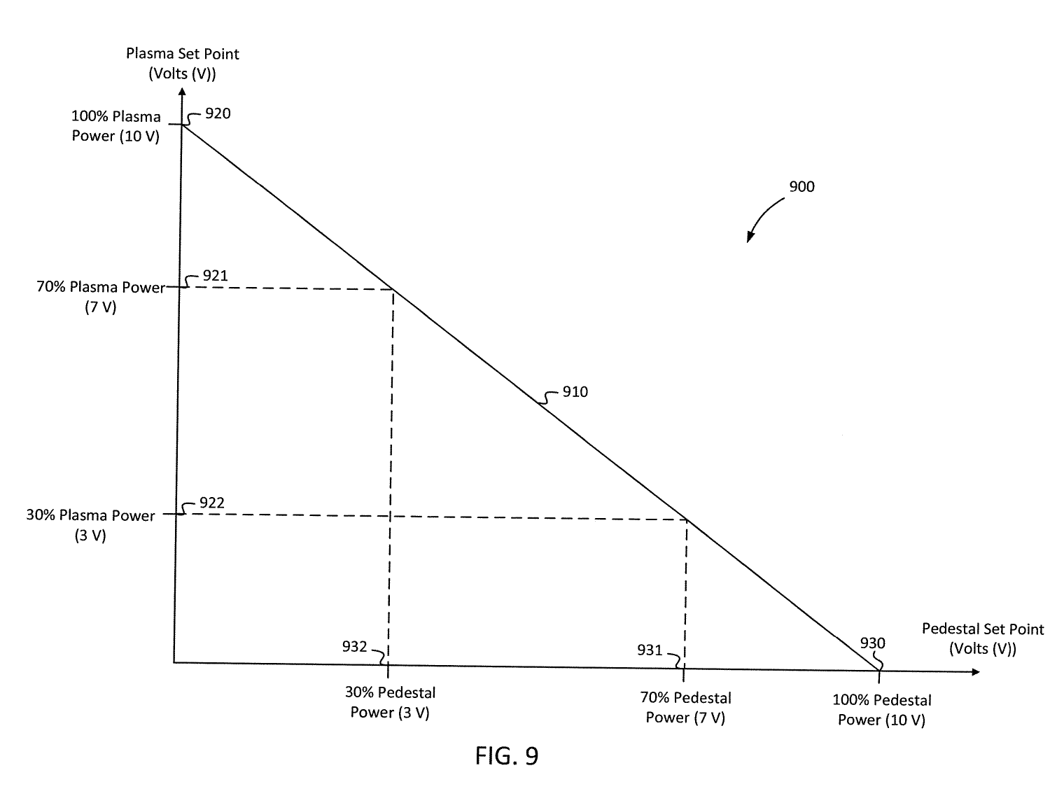

FIG. 9 depicts a plot illustrating the linear percentage relationship between the plasma power set point and the pedestal power set point in accordance with at least one embodiment. Plot 900 illustrates the linear percentage relationship 910 between the plasma power set point on the y-axis and the pedestal power set point on the x-axis. In some embodiments, the plasma power set point can have a range of set points (e.g., a range of 0 V to 10 V) which corresponds to a range of a signal representing energy provided to a semiconductor processing chamber to generate plasma in the semiconductor processing chamber, and the thermal energy generated by the plasma in the semiconductor processing chamber can depend on the plasma power set point. In some embodiments, the pedestal power set point can have a range of set points (e.g., a range of 0 V to 10 V) which corresponds a range of a signal representing energy provided to the pedestal to provide power and/or thermal energy to the pedestal.

Some embodiments can have a plasma power set point range of 0 V to 10 V and a pedestal power set point range of 0 V to 10 V, where 10 V represents the maximum power for both the plasma power set point and the pedestal power set point, and if the plasma power set point is set to X percent of the maximum plasma power, then the conditioned pedestal power set point is set to 100 minus X percent, of the maximum power that can be applied to the pedestal. In the example of diagram 900, if the plasma power is set to 100% or 10 V, then the corresponding pedestal power is modified to 0% or OV, meaning no power is applied to the pedestal and the pedestal has a minimal amount of thermal energy so that it can act like a heat sink to remove thermal energy from the semiconductor processing chamber. Also in the example, if the plasma power is set to 70% or 7 V, then the corresponding pedestal power is modified to 30% or 3V, and if the plasma power is set to 30% or 3 V, then the corresponding pedestal power is modified to 70% or 7 V.

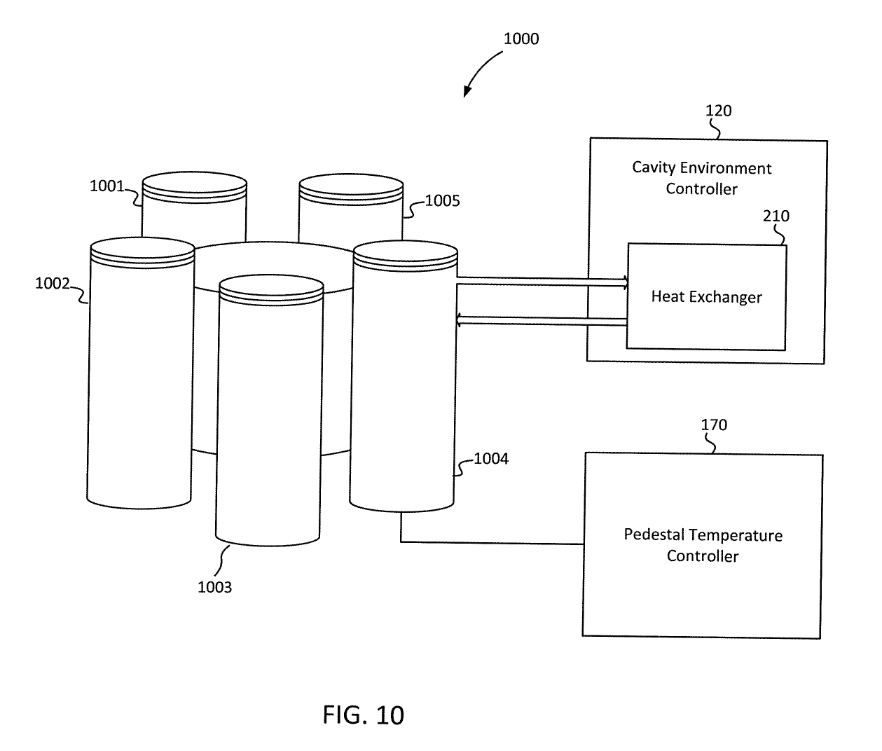

FIG. 10 depicts the semiconductor processing chamber temperature control system as part of a semiconductor processing system. In some embodiments, elements in FIG. 10 can have structures and/or functions equivalent to elements in FIG. 1 that are named and/or numbered similarly. The embodiment shown in diagram 1000 shows a semiconductor processing system, such as the Applied Materials Endura 5500 PVD system (available from Applied Materials, Santa Clara, Calif.), with semiconductor processing chamber 1004 modified as a semiconductor processing chamber temperature control system including cavity environment controller 120 and pedestal temperature controller 170. In some embodiments, more than one of semiconductor chambers 1001-1004 can be modified as a semiconductor processing chamber temperature control system.

Any of the above-described features can be implemented in software, hardware, firmware, circuitry, or any combination thereof. Note that the structures and constituent elements above, as well as their functionality, may be aggregated or combined with one or more other structures or elements. Alternatively, the elements and their functionality may be subdivided into constituent sub-elements, if any. As software, the above-described techniques may be implemented using various types of programming or formatting languages, frameworks, syntax, applications, protocols, objects, or techniques. For example, elements of FIG. 1 (or any subsequent figure), such as cavity environment controller 120 and pedestal temperature controller 170 (or any portion thereof) can represent one or more algorithms. Or, any of the elements can represent a portion of logic including a portion of hardware configured to provide constituent structures and/or functionalities. Any of the elements can represent a portion of hardware configured to provide constituent structures and/or functionalities.

For example, temperature controller 220 of FIG. 2 (including one or more components, or any of their subcomponents), and pedestal temperature controller 170 of FIG. 6 (including one or more components, or any of their subcomponents), can be implemented in one or more computing devices, processors, or servers including one or more processors configured to execute one or more algorithms in memory. Thus, an element (or a portion thereof) in FIG. 1 (or any subsequent figure) can represent one or more algorithms, or be implemented by one or more algorithms. Or, any of the elements can represent a portion of logic including a portion of hardware configured to provide constituent structures and/or functionalities. These can be varied and are not limited to the examples or descriptions provided.

As hardware and/or firmware, the above-described structures and techniques can be implemented using various types of programming or integrated circuit design languages, including hardware description languages, such as any register transfer language (“RTL”) configured to design field-programmable gate arrays (“FPGAs”), digital signal processor (“DSP”), application-specific integrated circuits (“ASICs”), multi-chip modules, or any other type of integrated circuit. For example, temperature controller 220 of FIG. 2 (including one or more components, or any of their subcomponents), and pedestal temperature controller 170 of FIG. 6 (including one or more components, or any of their subcomponents can be implemented in one or more computing devices or in one or more circuits, or a combination thereof. Thus, elements in FIG. 1 (or any subsequent figure) can represent one or more components of hardware. Or, any of the elements can represent a portion of logic including a portion of circuit configured to provide constituent structures and/or functionalities.

According to some embodiments, the term “circuit” can refer, for example, to any system including a number of components through which current flows to perform one or more functions, the components including discrete and complex components. Examples of discrete components include transistors, resistors, capacitors, inductors, diodes, and the like, and examples of complex components include memory, processors, analog circuits, digital circuits, and the like, including field-programmable gate arrays (“FPGAs”), application-specific integrated circuits (“ASICs”). Therefore, a circuit can include a system of electronic components and logic components (e.g., logic configured to execute instructions, such that a group of executable instructions of an algorithm, for example, and, thus, is a component of a circuit). According to some embodiments, the term “module” can refer, for example, to an algorithm or a portion thereof, and/or logic implemented in either hardware circuitry or software, or a combination thereof. According to some embodiments, the term “engine” can refer, for example, to an algorithm or a portion thereof, and/or logic implemented in either hardware circuitry or software, or a combination thereof (i.e., an engine can be implemented in as a circuit). In some embodiments, algorithms and/or the memory in which the algorithms are stored are “components” of a circuit. Thus, the term “circuit” can also refer, for example, to a system of components, including algorithms. These can be varied and are not limited to the examples or descriptions provided.

FIG. 11 illustrates an exemplary computing platform in accordance with various embodiments. In some examples, computing platform 1100 may be used to implement computer programs, applications, methods, processes, algorithms, or other software to perform the above-described techniques. Computing platform 1100 includes a bus 1102 or other communication mechanism for communicating information, which interconnects subsystems and devices, such as processor 1104, system memory 1106 (e.g., RAM, etc.), storage device 1108 (e.g., ROM, etc.), a communication interface 1113 (e.g., an Ethernet or wireless controller, a Bluetooth controller, etc.) to facilitate communications via a port on communication link 1121 to communicate, for example, with a computing device. Processor 1104 can be implemented with one or more central processing units (“CPUs”), such as those manufactured by Intel® Corporation, or one or more virtual processors, as well as any combination of CPUs and virtual processors. Computing platform 1100 exchanges data representing inputs and outputs via input-and-output devices 1101, including, but not limited to, keyboards, mice, audio inputs (e.g., speech-to-text devices), user interfaces, displays, monitors, cursors, touch-sensitive displays, and other I/O-related devices.

According to some examples, computing platform 1100 performs specific operations by processor 1104 executing one or more sequences of one or more instructions stored in system memory 1106, and computing platform 1100 can be implemented in a client-server arrangement, peer-to-peer arrangement, or as any mobile computing device, including smart phones and the like. Such instructions or data may be read into system memory 1106 from another computer readable medium, such as storage device 1108. In some examples, hard-wired circuitry may be used in place of or in combination with software instructions for implementation. Instructions may be embedded in software or firmware. The term “computer readable medium” refers to any tangible medium that participates in providing instructions to processor 1104 for execution. Such a medium may take many forms, including but not limited to, non-volatile media and volatile media. Non-volatile media includes, for example, optical or magnetic disks and the like. Volatile media includes dynamic memory, such as system memory 1106.

Common forms of computer readable media includes, for example, floppy disk, flexible disk, hard disk, magnetic tape, any other magnetic medium, CD-ROM, any other optical medium, punch cards, paper tape, any other physical medium with patterns of holes, RAM, PROM, EPROM, FLASH-EPROM, any other memory chip or cartridge, or any other medium from which a computer can read. Instructions may further be transmitted or received using a transmission medium. The term “transmission medium” may include any tangible or intangible medium that is capable of storing, encoding or carrying instructions for execution by the machine, and includes digital or analog communications signals or other intangible medium to facilitate communication of such instructions. Transmission media includes coaxial cables, copper wire, and fiber optics, including wires that comprise bus 1102 for transmitting a computer data signal.

In some examples, execution of the sequences of instructions may be performed by computing platform 1100. According to some examples, computing platform 1100 can be coupled by communication link 1121 (e.g., a wired network, such as LAN, PSTN, or any wireless network) to any other processor to perform the sequence of instructions in coordination with (or asynchronous to) one another. Computing platform 1100 may transmit and receive messages, data, and instructions, including program, i.e., application code, through communication link 1121 and communication interface 1113. Received program code may be executed by processor 1104 as it is received, and/or stored in memory 1106, or other non-volatile storage for later execution.

In the example shown, system memory 1106 can include various modules that include executable instructions to implement functionalities described herein. In the example shown, system memory 1106 includes a cavity temperature controller module 1154 configured to perform one or more functions to facilitate the control of the temperature in a cavity, and a pedestal temperature controller module 1158 configured to provide one or more functions described herein.

Various embodiments or examples of the invention can be implemented in numerous ways, including as a system, a process, an apparatus, or a series of program instructions on a computer readable medium such as a computer readable storage medium or a computer network where the program instructions are sent over optical, electronic, wireless, or other communication links. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims, and numerous alternatives, modifications, and equivalents are encompassed. Numerous specific details are set forth in the following description in order to provide a thorough understanding. These details are provided as examples and the described techniques may be practiced according to the claims without some or all of the accompanying details. For clarity, technical material that is known in the technical fields related to the examples has not been described in detail to avoid unnecessarily obscuring the description.

The description, for purposes of explanation, uses specific nomenclature to provide a thorough understanding of the various embodiments. However, it will be apparent that specific details are not required in order to practice the various embodiments. In fact, this description should not be read to limit any feature or aspect of any embodiment; rather features and aspects of one example can readily be interchanged with other examples. Notably, not every benefit described herein need be realized by each example of the various embodiments; rather any specific example may provide one or more of the advantages discussed above. In the claims, elements and/or operations do not imply any particular order of operation, unless explicitly stated in the claims. It is intended that the following claims and their equivalents define the scope of the various embodiments.

1. A system comprising:
a pedestal disposed in a semiconductor processing chamber;
a controller configured to receive data representing a plasma power set point and data representing a first pedestal power set point, the controller further configured to compare the data representing the plasma power set point and the data representing the first pedestal power set point to determine a second pedestal set point; and
a pedestal driver configured to receive data representing the second pedestal power set point and to generate an alternating current (“AC”) power signal corresponding to the second pedestal power set point,
wherein the pedestal is configured to receive the AC power signal that corresponds to the second pedestal power set point and to operate as a heat exchanger to remove thermal energy from the semiconductor processing chamber.

2. The system of claim 1, wherein the AC power signal is an alternating current signal with an amplitude determined by the second pedestal power set point, wherein the thermal energy of the pedestal is determined by the amplitude.

3. The system of claim 2, wherein the amplitude of the AC power signal is modulated as a function of the second pedestal power set point.

4. The system of claim 3, wherein the pedestal absorbs thermal energy from the semiconductor processing chamber when the thermal energy of the semiconductor processing chamber is greater than the thermal energy of the pedestal, wherein the pedestal operates as a heat sink.

5. The system of claim 4, wherein the controller is further configured to determine the presence of plasma in the semiconductor processing chamber, wherein the second pedestal power set point is equal to the first pedestal power set point when plasma is not present in the semiconductor processing chamber.

6. The system of claim 5, wherein the thermal energy of the pedestal is determined by the amplitude and a duty cycle of the AC power signal.

7. The system of claim 6, wherein the amplitude and the duty cycle of the AC power signal is modulated as a function of the second pedestal power set point.

8. The system of claim 1, wherein the second pedestal power set point has a linear percentage relationship to the plasma power set point.

9. The system of claim 1, wherein the plasma power set point is in a range of approximately 0 to 10 volts (V) and the first pedestal power set point is in a range of approximately 0 to 10 V.

10. The system of claim 1, where the second pedestal power set point is a conditioned pedestal set point.

11. A method comprising:
receiving data representative of a plasma power set point;
receiving data representative of a first pedestal power set point;
determining a second pedestal power set point by comparing the data representative of the plasma power set point and data representative of the first pedestal power set point;
generating an alternating current (“AC”) power signal that corresponds to the second pedestal power set point; and
exchanging thermal energy through a pedestal disposed in a semiconductor processing chamber to regulate thermal energy in the semiconductor processing chamber, wherein the amount of exchanged thermal energy is based on the AC power signal that corresponds to the second pedestal power set point.

12. The method of claim 11, wherein the AC power signal is an AC square wave with an amplitude determined by the second pedestal power set point, wherein the thermal energy of the pedestal is determined by the amplitude.

13. The method of claim 12, further comprising modulating the amplitude of the AC square wave as a function of the second pedestal power set point.

14. The method of claim 13, further comprising withdrawing thermal energy from the semiconductor processing chamber through the pedestal when the thermal energy of the semiconductor processing chamber is greater than the thermal energy of the pedestal, wherein the pedestal operates as a heat sink.

15. The method of claim 14, further comprising receiving data representative of the presence of plasma in the semiconductor processing chamber, wherein the second pedestal power set point is equal to the first pedestal power set point when plasma is not present in the semiconductor processing chamber.

16. The method of claim 15, wherein the thermal energy of the pedestal is determined by either the amplitude or a duty cycle of the AC square wave, or both.

17. The method of claim 16, further comprising modulating the amplitude and the duty cycle of the AC square wave as a function of the second pedestal power set point.

18. The method of claim 11, wherein the second pedestal power set point has a linear percentage relationship to the plasma power set point.

19. The method of claim 11, wherein the plasma power set point is in a range of approximately 0 to 10 volts (V) and the pedestal power set point is in a range of approximately 0 to 10 V.

20. The method of claim 11, wherein the second pedestal power set point is a conditioned pedestal power set point.
